(19) United States
(12) Patent Application Publication
(10) Pub. No.: US 2023/0077048 A1
(43) Pub. Date: Mar. 9, 2023

(54) DISPLAY DEVICE AND METHOD FOR MANUFACTURING DISPLAY DEVICE

(71) Applicant: KYOCERA Corporation, Kyoto-shi, Kyoto (JP)

(72) Inventors: Fumiaki OSHIRO, Kusatsu-shi, Shiga (JP); Hiroaki ITO, Ritto-shi, Shiga (JP)

(21) Appl. No.: 17/794,235

(22) PCT Filed: Jan. 13, 2021
(86) PCT No.: PCT/JP2021/000901

§ 371 Date: Jul. 20, 2022

(30) Foreign Application Priority Data
Jan. 24, 2020 (JP) 2020-010325
Dec. 11, 2020 (JP) 2020-206246

(51) Int. Cl. H01L 33/62; H01L 33/38; H01L 25/075; H01L 33/00

(52) U.S. Cl. CPC H01L 33/62; H01L 33/382; H01L 25/0753; H01L 33/005; H01L 2933/0016; H01L 2933/0066

(57) ABSTRACT

A display device includes a substrate having a first surface and a second surface opposite to the first surface, a pixel unit located on the first surface and including a light emitter, a first connection pad located on the first surface adjacent to an edge of the substrate and connected to the pixel unit, a second connection pad on the second surface adjacent to the edge, and a connection conductor extending from the first surface to the second surface and connecting the first connection pad and the second connection pad. The first connection pad has a center at a position different from a center of the second connection pad as viewed in plan.

### TECHNICAL FIELD

The present disclosure relates to a display device and a method for manufacturing a display device.

### BACKGROUND OF INVENTION

A known display device includes pixel units each including self-luminous light emitters such as light-emitting diodes or organic electroluminescence elements (refer to, for example, Patent Literature 1). Another known display device is a composite large display device (hereafter also referred to as a multi-display) including multiple tiled display devices (refer to, for example, Patent Literature 2).

Multi-displays have recently been improved to have higher image quality. Such a multi-display is expected to include display devices each including a higher definition display portion with a smaller pixel pitch and a narrower bezel around the display portion. To achieve higher definition and narrower bezels, known display devices may improve interconnection or routing of drive wiring for the display portions.

### CITATION LIST

### Patent Literature

Patent Literature 1: Japanese Unexamined Patent Application Publication No. 2017-009725
Patent Literature 2: Japanese Unexamined Patent Application Publication No. 2015-194993

### SUMMARY

A display device according to an aspect of the present disclosure includes a substrate having a first surface and a second surface opposite to the first surface, a pixel unit located on the first surface and including a light emitter, a first connection pad located on the first surface adjacent to an edge of the substrate and connected to the pixel unit, a second connection pad on the second surface adjacent to the edge, and a connection conductor extending from the first surface to the second surface and connecting the first connection pad and the second connection pad. The first connection pad has a center at a position different from a center of the second connection pad as viewed in plan.

A method for manufacturing a display device according to another aspect of the present disclosure includes preparing a mother substrate having a first surface and a second surface opposite to the first surface and including at least one display device area, forming a plurality of pixel areas each including an electrode pad in the at least one display device area on the first surface, forming a plurality of first connection pads in the at least one display device area on the first surface adjacent to an edge of the at least one display device area to connect the plurality of first connection pads to the plurality of electrode pads, forming a plurality of second connection pads in the at least one display device area on the second surface adjacent to the edge of the at least one display device area to cause a smallest value of distances between the edge of the at least one display device area and the plurality of electrode pads and a smallest value of distances between the edge and the plurality of first connection pads to be each shorter than a smallest value of distances between the edge and the plurality of second connection pads as viewed in plan, and cutting the mother substrate along the edge of the at least one display device area into a display device substrate including the at least one display device area.

### BRIEF DESCRIPTION OF THE DRAWINGS

The objects, features, and advantages of the present disclosure will become more apparent from the following detailed description and the drawings.

FIG. 1 is a schematic circuit diagram of a display device according to an embodiment of the present disclosure, illustrating circuit wiring and other components on a first surface of the display device.

FIG. 2 is a schematic circuit diagram of the display device according to the embodiment of the present disclosure, illustrating circuit wiring and other components on a second surface of the display device.

FIG. 3 is a plan view of the display device according to the embodiment of the present disclosure, illustrating its main part in an enlarged manner.

FIG. 4 is a cross-sectional view taken along line A1-A2 in FIG. 3.

FIG. 5 is a cross-sectional view taken along line A3-A4 in FIG. 3.

FIG. 6 is a cross-sectional view taken along line A5-A6 in FIG. 3.

FIG. 7 is a plan view of a display device according to another embodiment of the present disclosure, illustrating its main part in an enlarged manner.

FIG. 8A is a plan view of a display device according to another embodiment of the present disclosure, illustrating its main part in an enlarged manner.

FIG. 8B is a cross-sectional view taken along line A7-A8 in FIG. 8A.

FIG. 9 is a flowchart of a method for manufacturing the display device according to an embodiment of the present disclosure.

FIG. 10 is a plan view of a display device according to another embodiment of the present disclosure, illustrating its main part in an enlarged manner.

FIG. 11 is a plan view of a display device according to another embodiment of the present disclosure, illustrating its main part in an enlarged manner.

FIG. 12 is a plan view of a display device according to another embodiment of the present disclosure, illustrating its main part in an enlarged manner.

### DESCRIPTION OF EMBODIMENTS

A display device according to one or more embodiments of the present disclosure will now be described with reference to the drawings. Each figure referred to below illustrates main components and other elements of the display device according to one or more embodiments of the present disclosure. The display device according to the embodiments of the present disclosure may thus include known components not illustrated in the figures, such as circuit boards, wiring conductors, ICs, and LSI circuits.

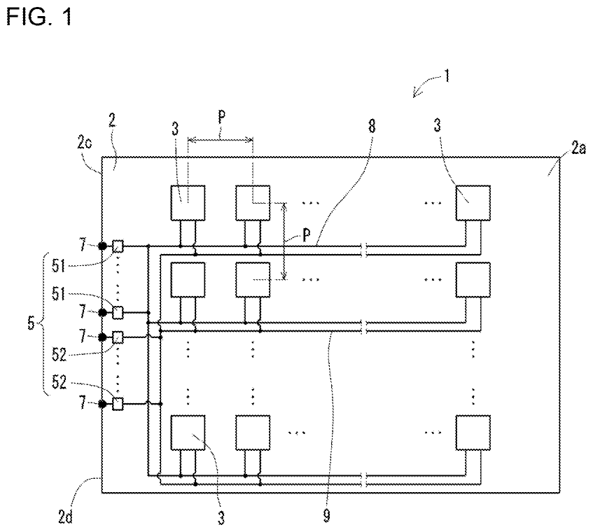

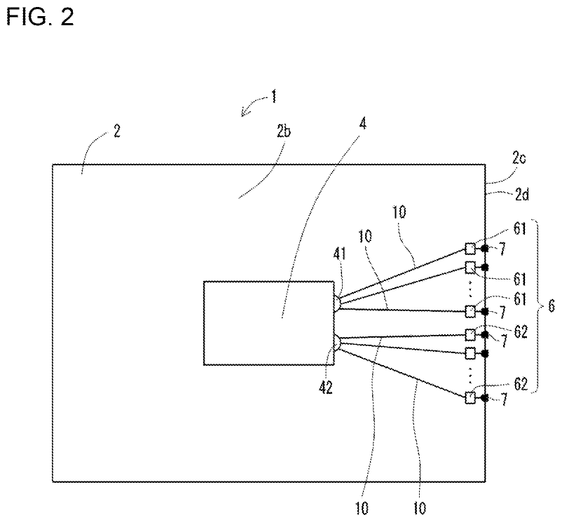

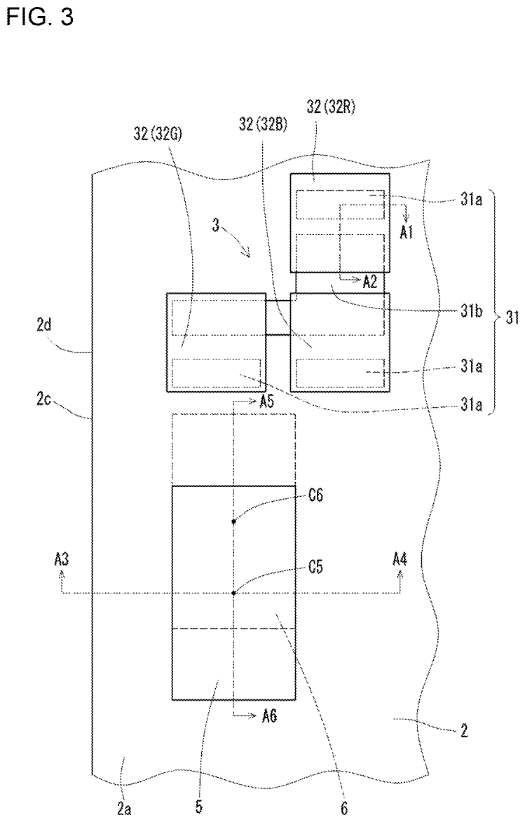

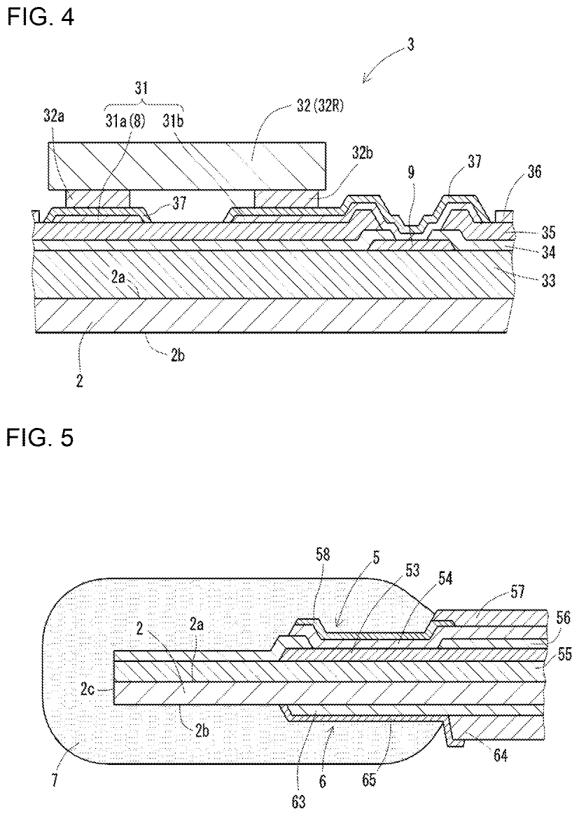

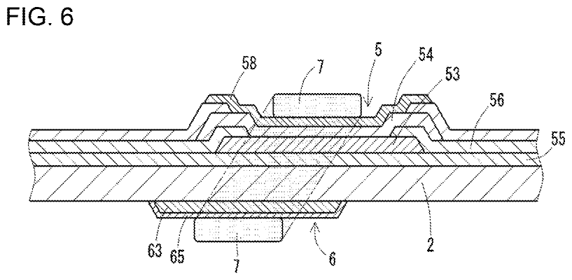

FIG. 1 is a schematic circuit diagram of a display device according to an embodiment of the present disclosure, illustrating circuit wiring and other components on a first surface of the display device. FIG. 2 is a schematic circuit diagram of the display device according to the embodiment of the present disclosure, illustrating circuit wiring and other components on a second surface of the display device. FIG. 3 is a plan view of the display device according to the embodiment of the present disclosure, illustrating its main part in an enlarged manner. FIG. 4 is a cross-sectional view taken along line A1-A2 in FIG. 3. FIG. 5 is a cross-sectional view taken along line A3-A4 in FIG. 3. FIG. 6 is a cross-sectional view taken along line A5-A6 in FIG. 3. FIG. 1 is a diagram of a substrate as viewed from the first surface. FIG. 2 is a diagram of the substrate as viewed from the second surface. For simplicity, FIG. 3 illustrates a pixel unit including an electrode pad and a light emitter without illustrating other elements. In FIG. 3, a side conductor as a connection conductor is not illustrated.

A display device 1 includes a substrate 2, a pixel unit 3, a first connection pad 5, a second connection pad 6, and a side conductor (also referred to as side wiring) 7 as a connection conductor.

The substrate 2 has a first surface 2a and a second surface 2b opposite to the first surface 2a. The pixel unit 3 is on the first surface 2a and includes a light emitter 32. The first connection pad 5 is on the first surface 2a adjacent to an edge 2d of the substrate 2 and is connected to the pixel unit 3. The second connection pad 6 is on the second surface 2b adjacent to the edge 2d. The side conductor 7 as the connection conductor extends from the first surface 2a to the second surface 2b and connects the first connection pad 5 and the second connection pad 6. In the display device 1 according to one or more embodiments of the present disclosure, a center C5 of the first connection pad 5 is located at a position different from a center C6 of the second connection pad 6 as viewed in plan.

In one or more embodiments of the present disclosure, the display device 1 with the above structure produces the effects described below. The display device 1 can reliably connect the first connection pad 5 and the second connection pad 6 and also increase their positioning flexibility. The first connection pad 5 and the second connection pad 6 are thus positioned to achieve a narrow bezel and are also connected together reliably. The display device 1 thus has higher reliability, higher definition, and a narrower bezel. In one or more embodiments of the present disclosure, the display device 1 can form a multi-display with a uniform pixel pitch and thus with higher image quality. One first connection pad 5 may be connected to multiple second connection pads 6, or multiple first connection pads 5 may be connected to one second connection pad 6. This structure increases, for example, versatility and reduces voltage drops as described later.

The first connection pad 5 may have the center C5 defined as, for example, the geometric center or the center of gravity of the first connection pad 5. For the center C5 being the geometric center of the first connection pad 5, the first connection pad 5 may be in the shape of a symmetric polygon, such as a rectangle (a square or an oblong), a rhombus, or a parallelogram, and may have the intersection of diagonals defined as the center 5C. For the first connection pad 5 being circular, the center 5C may be the center defining the radius. For the first connection pad 5 being elliptic, the center 5C may be the intersection of the major and minor axes. For the first connection pad 5 having another asymmetric shape, the center 5C may be the center of gravity. The same or similar applies to the shape and the center C6 of the second connection pad 6.

In the display device 1 according to one or more embodiments of the present disclosure, as illustrated in FIG. 3, the first connection pad 5 and the second connection pad 6 may include an overlap portion as viewed in plan. This structure facilitates reliable connection between the first connection pad 5 and the second connection pad 6. For the first connection pad 5 and the second connection pad 6 having different sizes (areas), the overlap portion may have, but is not limited to, a size of about 1 to 70% of the larger one of these pads. For the first connection pad 5 and the second connection pad 6 having the same size, the overlap portion may have, but is not limited to, a size of about 1 to 80% of one of these pads.

In the display device 1, the first connection pad 5 may have the center C5 aligned with the second connection pad 6, or the second connection pad 6 may have the center C6 aligned with the first connection pad 5, or both. This structure allows more reliable connection between the first connection pad 5 and the second connection pad 6.

As illustrated in FIG. 3, in the display device 1, the center C5 of the first connection pad 5 may be shifted from the center C6 of the second connection pad 6 in the direction along the edge 2d of the substrate 2. The center C5 and the center C6 shifted from each other in this direction do not cause an increase in the size of the bezel. The display device 1 can thus easily achieve a narrow bezel.

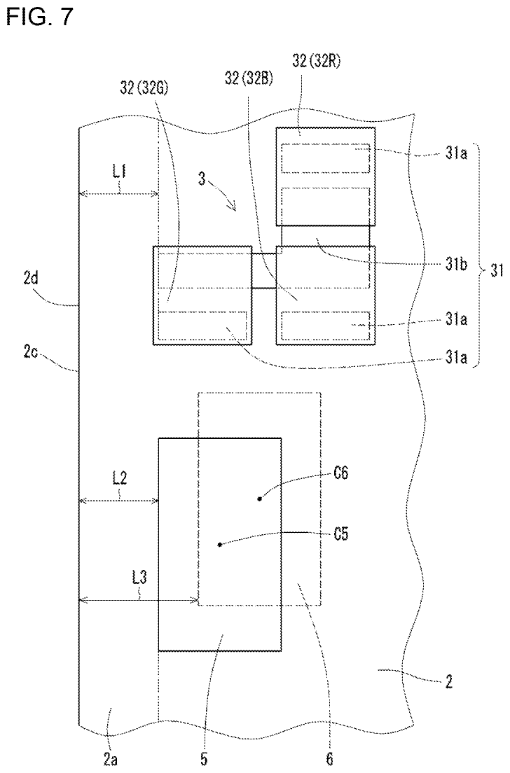

As illustrated in FIG. 7, in the display device 1, the first connection pad 5 may have the center C5 shifted from the center C6 of the second connection pad 6 in a direction intersecting with the edge 2d of the substrate 2. The second connection pad 6 may have the center C6 farther from the edge 2d of the substrate 2 than the center C5 of the first connection pad 5. With the second connection pad 6 being away from the edge 2d of the substrate 2, the substrate 2 can be cut with a laser beam irradiating its second surface 2b with less degradation of the second connection pad 6 caused by breakage or other damage from laser irradiation or heat. The above intersecting direction may be orthogonal to the edge 2d of the substrate 2, or may be inclined at an angle of, but not limited to, about 10 to 80° relative to the edge 2d of the substrate 2.

For the substrate 2 being cut with a laser beam irradiating its second surface 2b, the second connection pad 6 may have a dimension adjacent to the edge 2d (the dimension along the edge 2d) smaller than the dimension of the second connection pad 6 opposite to the edge 2d (the dimension along the edge 2d) to reduce degradation of the second connection pad 6 caused by breakage or other damage from laser irradiation or heat. For example, the second connection pad 6 may be in the shape of a trapezoid with its side adjacent to the edge 2d being the upper base and with its side opposite to the edge 2d being the lower base.

In the display device 1, the second connection pad 6 may have the center C6 farther from the edge 2d of the substrate 2 than the center C5 of the first connection pad 5, and the second connection pad 6 may have a dimension adjacent to the edge 2d (the dimension along the edge 2d) smaller than the dimension of the second connection pad 6 opposite to the edge 2d (the dimension along the edge 2d). The substrate 2 with this structure can be cut with a laser beam irradiating its second surface 2b with still less degradation of the second connection pad 6 caused by breakage or other damage from laser irradiation or heat.

As illustrated in FIG. 5, the substrate 2 in the display device 1 may have a side surface 2c connecting the first surface 2a and the second surface 2b. The connection conductor may include the side conductor 7 extending from the first surface 2a through the side surface 2c to the second surface 2b. This structure can eliminate or minimize the bezel on the substrate 2.

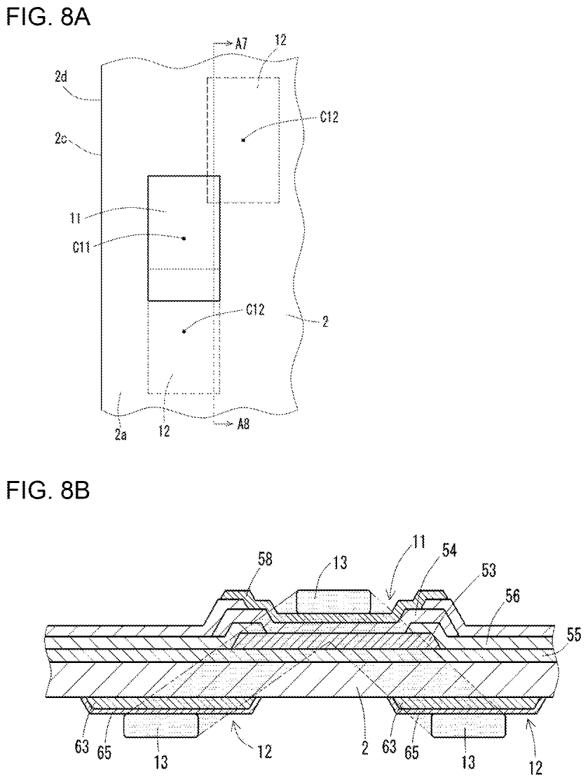

As illustrated in FIG. 8B, the side conductor 7 in the display device 1 may connect one first connection pad 5 and multiple second connection pads 6. In this case, the first connection pad 5 can receive, for example, different signals at different times, or receive a signal resulting from combination of different signals, thus increasing the versatility. The first connection pad 5 and multiple second connection pads 6 each may be a junction pad for wiring for feeding the power supply voltage. In this case, the multiple second connection pads 6 are connected to multiple wiring patterns on the second surface 2b to substantially increase the area and/or the cross section of the wiring for feeding the power supply voltage. This structure can reduce the resistance of the wiring for feeding the power supply voltage and reduce voltage drops in the wiring. This can reduce the likelihood of, for example, uneven luminance of the display image, thus improving the image quality.

In the display device 1 with the structure illustrated in FIG. 8B, the side conductor 7 may be thicker on the first connection pad 5 than on the second connection pad 6. This structure reduces the likelihood that, for example, signals at different voltage levels (potentials) input into the first connection pad 5 undergo voltage drops caused by the resistance of the first connection pad 5 to have a potential difference that is not large enough to distinguish these signals from each other. For the first connection pad 5 and the multiple second connection pads 6 each being a junction pad for wiring for feeding the power supply voltage, the structure reduces the resistance between the junction pads and reduces voltage drops in the wiring for feeding the power supply voltage. This can reduce the likelihood of, for example, uneven luminance of the display image, thus improving the image quality.

The substrate 2 is, for example, a transparent or opaque glass substrate, a plastic substrate, or a ceramic substrate. The substrate 2 has the first surface 2a, the second surface 2b opposite to the first surface 2a, and the side surface 2c connecting the first surface 2a and the second surface 2b. The substrate 2 may be triangular, rectangular, trapezoidal, circular, elliptic, pentagonal, hexagonal, or in any other shape. For the substrate 2 being triangular, rectangular, or hexagonal, in particular, for example, multiple display devices may be efficiently tiled. In the present embodiment, the substrate 2 is rectangular, as illustrated in, for example, FIG. 1.

Multiple pixel units 3 may be included. The pixel units 3 are located on the first surface 2a. As illustrated in, for example, FIG. 1, the pixel units 3 are arranged in a matrix at a predetermined pixel pitch P. The pixel pitch P may be, for example, about 40 to 400 μm, about 40 to 120 μm, about 60 to 100 μm, or about 80 μm.

Each pixel unit 3 includes an electrode pad 31 and a light emitter 32 electrically connected to the electrode pad 31.

The light emitter 32 is, for example, a self-luminous light emitter such as a light-emitting diode (LED), an organic electroluminescence element, or a semiconductor laser element. In the present embodiment, the light emitter 32 is an LED. The light emitter 32 may be a micro-light-emitting diode (micro-LED). In this case, the light emitter 32 connected to the electrode pad 31 may be rectangular as viewed in plan with each side having a length of about 1 to 100 μm inclusive, or about 3 to 10 μm inclusive.

The light emitter 32 is electrically connected to the electrode pad 31 with a conductive bond, such as a conductive adhesive, solder, or an anisotropic conductive film (ACF). The electrode pad 31 in the present embodiment includes an anode pad 31a and a cathode pad 31b. The anode pad 31a is electrically connected to an anode terminal 32a of the light emitter 32. The cathode pad 31b is electrically connected to a cathode terminal 32b of the light emitter 32.

Each pixel unit 3 may include multiple anode pads 31a, a common cathode pad 31b, and multiple light emitters 32. The anode pads 31a are electrically connected to the anode terminals 32a of the light emitters 32. The common cathode pad 31b is electrically connected to the cathode terminals 32b of the light emitters 32. The light emitters 32 may include a light emitter 32R that emits red light, a light emitter 32G that emits green light, and a light emitter 32B that emits blue light. In this case, each pixel unit 3 enables display of color tones. Each pixel unit 3 may include, instead of the light emitter 32R that emits red light, a light emitter that emits orange, red-orange, red-violet, or violet light. Each pixel unit 3 may include, instead of the light emitter 32G that emits green light, a light emitter that emits yellow-green light.

The substrate 2 includes a drive unit including a power supply circuit 4 on the second surface 2b. The drive unit may include a gate signal line drive (gate driver), a source signal line drive (source driver), or another control circuit. The drive unit may be a thin film circuit including driving elements such as ICs, a circuit board such as a flexible printed circuit (FPC) incorporating the driving elements, and a semiconductor layer including low-temperature polycrystalline silicon (LTPS).

As illustrated in, for example, FIG. 2, the power supply circuit 4 is located on the second surface 2b. The power supply circuit 4 generates a first power supply voltage VDD and a second power supply voltage VSS applicable to the pixel units 3. The power supply circuit 4 includes a VDD terminal 41 for outputting the first power supply voltage VDD and a VSS terminal 42 for outputting the second power supply voltage VSS. The first power supply voltage VDD is an anode voltage of, for example, about 10 to 15 V. The second power supply voltage VSS is lower than the first power supply voltage VDD and is a cathode voltage of, for example, about 0 to 3 V.

The power supply circuit 4 includes a control circuit for controlling, for example, the emission or non-emission state and the light intensity of the light emitters 32. The power supply circuit 4 may be, for example, a thin film circuit on the second surface 2b of the substrate 2. In this case, the thin film circuit may include, for example, a semiconductor layer including LTPS formed directly on the second surface 2b with a thin film formation method such as CVD. The power supply circuit 4 may include an IC chip as a control circuit.

The first connection pads 5 are on the first surface 2a adjacent to the edge of the substrate 2. In other words, the first connection pads 5 are near the edge 2d of the substrate 2. Each first connection pad 5 may be located at a distance of about half the pixel pitch P (e.g., about 40 to 400 μm) of the pixel units 3 from the edge 2d of the substrate 2. For multiple display devices being tiled with light absorbers placed between adjacent display devices, for example, each first connection pad 5 may be located at a distance shorter than half the pixel pitch P of the pixel units 3 from the edge 2d of the substrate 2. The first connection pads 5 include multiple first wiring pads 51 and multiple second wiring pads 52. The first wiring pads 51 are used to apply the first power supply voltage VDD to the pixel units 3. The second wiring pads 52 are used to apply the second power supply voltage VSS to the pixel units 3.

The display device 1 includes a first wiring pattern 8 and a second wiring pattern 9. The first wiring pattern 8 and the second wiring pattern 9 are located on the first surface 2a. The first wiring pattern 8 and the second wiring pattern 9 include, for example, Mo/Al/Mo or MoNd/AlNd/MoNd. Mo/Al/Mo is a stack of a Mo layer, an Al layer, and a Mo layer in this order. The same or similar applies to the others. As illustrated in, for example, FIG. 1, the first wiring pattern 8 connects the pixel units 3 and the first wiring pads 51, and the second wiring pattern 9 connects the pixel units 3 and the second wiring pads 52. The first wiring pattern 8 and the second wiring pattern 9 may be planar and electrically insulated from each other with insulating layers (insulating layers 34 and 35 described later) between them. The first wiring pattern 8 may include the anode pads 31a of the electrode pads 31 as parts of the first wiring pattern 8.

The second connection pads 6 are located on the second surface 2b. The second connection pads 6 are near the edge 2d of the substrate 2. The second connection pads 6 include multiple third wiring pads 61 and multiple fourth wiring pads 62. The third wiring pads 61 are used to apply the first power supply voltage VDD to the pixel units 3. The fourth wiring pads 62 are used to apply the second power supply voltage VSS to the pixel units 3.

The display device 1 includes as many first wiring pads 51 as the third wiring pads 61, and as many second wiring pads 52 as the fourth wiring pads 62. Each first wiring pad 51 may at least partially overlap one or more of the third wiring pads 61 as viewed in plan. Each second wiring pad 52 may at least partially overlap one or more of the fourth wiring pads 62 as viewed in plan.

The display device 1 includes a third wiring pattern 10. The third wiring pattern 10 is located on the second surface 2b. The third wiring pattern 10 includes, for example, Mo/Al/Mo or MoNd/AlNd/MoNd. As illustrated in, for example, FIG. 2, the third wiring pattern 10 connects the VDD terminal 41 in the power supply circuit 4 and the third wiring pads 61, and connects the VSS terminal 42 in the power supply circuit 4 and the fourth wiring pads 62.

The display device 1 includes multiple connection conductors extending from the first surface 2a to the second surface 2b and connecting the first connection pads 5 and the second connection pads 6. The connection conductors may be side conductors 7 extending from the side surface 2c to the first surface 2a and to the second surface 2b of the substrate. The side conductors 7 electrically connect the first connection pads 5 and the second connection pads 6. The side conductors 7 electrically connect the first wiring pads 51 and the third wiring pads 61, and electrically connect the second wiring pads 52 and the fourth wiring pads 62. The connection conductors are not limited to the side conductors 7 but may be feedthrough conductors located at the periphery of the substrate 2 and extending from the first surface 2a through to the second surface 2b. However, the side conductors 7 may be used to effectively eliminate or minimize the bezel on the substrate 2.

The pixel unit 3, the first connection pad 5, and the second connection pad 6 will now be described in detail with reference to FIGS. 3 to 6.

As illustrated in FIG. 3, each pixel unit 3 in the present embodiment includes the electrode pad 31 including three anode pads 31a and a cathode pad 31b. Each pixel unit 3 may include the light emitter 32R that emits red light, the light emitter 32G that emits green light, and the light emitter 32B that emits blue light. The light emitters 32R, 32G, and 32B may be arranged in an L shape as viewed in plan as illustrated in, for example, FIG. 3. This allows the pixel unit 3 to be smaller as viewed in plan, and to be compact and square as viewed in plan. The display device 1 thus includes pixels with higher density, enabling high-quality image display.

As illustrated in, for example, FIG. 4, each pixel unit 3 includes insulating layers 33 to 36 located on the first surface 2a of the substrate 2. The insulating layers 33 to 36 are inorganic insulating layers including, for example, SiO₂ or Si₃N₄, or organic insulating layers including, for example, an acrylic resin or polycarbonate. For example, the insulating layers 34 and 35 are inorganic insulating layers, and the insulating layers 33 and 35 are organic insulating layers. Although not illustrated, a thin-film transistor (TFT) or another element for controlling the light emission of the light emitter 32 is located inside the insulating layer 33 nearest the substrate 2 among the insulating layers 33 to 36 or between the insulating layer 33 and the substrate 2. The insulating layers 34 and 35 are located between the first wiring pattern 8 and the second wiring pattern 9 and insulating them from each other.

The light emitter 32 includes the anode terminal 32a electrically connected to the anode pad 31a being a part of the first wiring pattern 8 with, for example, an ACF. The light emitter 32 includes the cathode terminal 32b electrically connected to the cathode pad 31b in an opening in the first wiring pattern 8 with, for example, an ACF. The anode pad 31a and the cathode pad 31b are electrically insulated from each other by the opening (cutout) around the anode pad 31a in the first wiring pattern 8. The cathode pad 31b is routed along the surfaces of the insulating layers 35 and 36 and the inner wall of the opening in the insulating layers 35 and 36 to be electrically connected to the second wiring pattern 9. The anode pad 31a and the cathode pad 31b may have their surfaces coated with a transparent conductive layer 37 of, for example, indium tin oxide (ITO) or indium zinc oxide (IZO).

The first connection pad 5 and the second connection pad 6 are made of a conductive material. The first connection pad 5 and the second connection pad 6 may include a single metal layer, or multiple metal layers stacked on one another. The first connection pad 5 and the second connection pad 6 include, for example, Al, Al/Ti, Ti/Al/Ti, Mo, Mo/Al/Mo, MoNd/AlNd/MoNd, Cu, Cr, Ni, or Ag. MoNd is an alloy of Mo and Nd. In the example of FIGS. 5 and 6, the first connection pad 5 includes two metal layers 53 and 54 stacked on each other and located on an insulating layer 55 on the first surface 2a of the substrate 2. In the example of FIGS. 5 and 6, the second connection pad 6 includes a single metal layer 63 located on the second surface 2b of the substrate 2. FIG. 5 illustrates an insulating protective layer (overcoat) 64.

As illustrated in, for example, FIG. 5, the first connection pad 5 including the metal layers 53 and 54 stacked on each other may include an insulating layer 56 partly between the metal layers 53 and 54. The first connection pad 5 may include an insulating layer 57 at its inward (right in FIG. 5) end on the first surface 2a. This reduces the likelihood of short-circuiting between the first connection pad 5 and a wiring conductor or another element located inward on the first surface 2a. The insulating layer 55 is made of, for example, SiO₂, Si₃N₄, or a polymeric material such as an acrylic resin. The first connection pad 5 may have its surface coated with a transparent conductive layer 58 of, for example, ITO or IZO. The second connection pad 6 may have its surface coated with a transparent conductive layer 65 of, for example, ITO or IZO.

As illustrated in, for example, FIGS. 5 and 6, the side conductor 7 extends from the side surface 2c to the first surface 2a and to the second surface 2b and connects the first connection pad 5 and the second connection pad 6. As illustrated in, for example, FIG. 6, the side conductor 7 may extend obliquely from the side surface 2c relative to the thickness direction of the substrate 2 (the vertical direction in FIG. 6). This structure increases the positioning flexibility of the first connection pad 5 and the second connection pad 6. The structure allows, for example, one first connection pad 5 to be connected to multiple second connection pads 6, allows multiple first connection pads 5 to be connected to one second connection pad 6, or allows multiple first connection pads 5 to be connected to multiple second connection pads 6. The side conductor 7 may include a conductive paste containing conductive particles of, for example, Ag, Cu, Al, or stainless steel, an uncured resin component, an alcohol solvent, and water. The conductive paste may be applied to an intended portion from the side surface 2c to the first surface 2a and to the second surface 2b and cured by heating, photocuring using ultraviolet ray irradiation, or a combination of photocuring and heating. The side conductor 7 may also be formed with a thin film formation method such as plating, vapor deposition, or CVD. The side surface 2c may include a preformed groove in the portion to receive the side conductor 7. This allows the conductive paste that forms the side conductor 7 to be easily received in the intended portion on the side surface 2c.

Although not illustrated, the display device 1 includes multiple gate signal lines and multiple source signal lines intersecting with the gate signal lines on the first surface 2a. Each pixel unit 3 includes multiple first electrode pads connected to the gate signal lines, multiple second electrode pads connected to the source signal lines, and a TFT for driving the light emitter connected to the first electrode pads and the second electrode pads. Although not illustrated, the display device 1 includes, on the second surface 2b, multiple third electrode pads electrically connected to the first electrode pads, and multiple fourth electrode pads electrically connected to the second electrode pads. The first electrode pads and the third electrode pads may be electrically connected to each other with, for example, side conductors having a structure the same or similar to the structure of the side conductors 7. The second electrode pads and the fourth electrode pads may be electrically connected to each other with, for example, side conductors having a structure the same or similar to the structure of the side conductors 7. The third electrode pads may be connected to the gate signal line drive (gate driver) located on the second surface 2b with, for example, back wiring. The fourth electrode pads may be connected to the source signal line drive (source driver) located on the second surface 2b with, for example, back wiring. The gate signal line drive and the source signal line drive may be included in the power supply circuit 4.

As illustrated in, for example, FIG. 3, in the display device 1, at least one of the first connection pads 5 may have the center C5 shifted from the center C6 of the second connection pad 6 connected to the first connection pad 5 in the direction along the edge 2d as viewed in plan. The display device 1 permits the shift between the center C5 and the center C6 as viewed in plan to increase the positioning flexibility of the first connection pads 5 and the second connection pads 6. This allows the first connection pads 5 and the second connection pads 6 to be all located adjacent to the edge 2d, achieving higher definition and a narrower bezel of the display device 1.

The display device 1 includes the center C5 and the center C6 shifted in the direction along the edge 2d to increase the positioning flexibility of the first connection pads 5 and the second connection pads 6. This reduces the likelihood of variations in the pixel pitch P, thus improving the image quality of the display device 1.

As illustrated in, for example, FIGS. 5 and 6, the display device 1 includes the side conductor 7 connecting the first connection pad 5 and the second connection pad 6. This structure can reliably connect the first connection pad 5 and the second connection pad 6 with their centers C5 and C6 shifted from each other. The display device 1 thus has higher reliability.

As described above, the display device 1 can reliably connect the first connection pad 5 and the second connection pad 6 and also increase their positioning flexibility. The display device 1 thus has higher reliability, higher definition, and a narrower bezel. The display device 1 can form a multi-display with higher image quality.

A display device according to another embodiment of the present disclosure will now be described with reference to FIG. 7. FIG. 7 is a plan view of a display device according to another embodiment of the present disclosure, illustrating its main part in an enlarged manner. For simplicity, FIG. 7 illustrates a pixel unit including an electrode pad and a light emitter without illustrating other elements. In FIG. 7, the side conductor is not illustrated.

As illustrated in, for example, FIG. 7, in the display device 1, at least one of the first connection pads 5 may have the center C5 shifted from the center C6 of the second connection pad 6 connected to the first connection pad 5 in the direction along the edge 2d (the vertical direction in FIG. 7) or in a direction intersecting with the edge 2d, for example, orthogonal to the edge 2d (the horizontal direction in FIG. 7), as viewed in plan. This structure can further increase the positioning flexibility of the first connection pads 5 and the second connection pads 6, achieving a narrower bezel of the display device 1 more easily. The display device 1 thus has higher reliability, higher definition, and a narrower bezel, and can form a multi-display with higher image quality. Shifting the center C5 from the center C6 in the direction orthogonal to the edge 2d may cause variations in the pixel pitch P. In this case, the center C5 may be shifted from the center C6 in the direction along the edge 2d alone.

In the display device 1, the center C5 may be nearer the edge 2d than the center C6, or the center C6 may be nearer the edge 2d than the center C5. For manufacturing the display device 1, the mother substrate including the first connection pads 5 and the second connection pads 6 may be cut with a laser beam irradiating its second surface 2b. In this case, the laser beam causes less damage to the second connection pads 6 with their centers C6 farther from the edge 2d than the centers C5.

As illustrated in, for example, FIG. 7, the display device 1 may have a first distance L1 and a second distance L2 each shorter than a third distance L3 as viewed in plan. The first distance L1 is the smallest value of the distances between the edge 2d of the substrate 2 and the electrode pads 31. The second distance L2 is the smallest value of the distances between the edge 2d and the first connection pads 5. The third distance L3 is the smallest value of the distances between the edge 2d and the second connection pads 6. For the electrode pads 31 including multiple anode pads 31a and multiple cathode pads 31b, the first distance L1 is defined as the distance between the edge 2d and the pad 31a or 31b nearest the edge 2d.

The display device 1 having the first distance L1 shorter than the third distance L3 allows the electrode pad 31 nearest the edge 2d among the electrode pads 31 to be located adjacent to the edge 2d. For example, the electrode pad 31 nearest the edge 2d among the electrode pads 31 can be located at a distance of about half the pixel pitch P from the edge 2d. In other words, the outermost pixel units 3 of the pixel units 3 arranged in a matrix can be located at a distance of about half the pixel pitch P from the edge 2d. A display device 1 can thus be combined with another display device 1 to form a multi-display to have a pixel pitch between these display devices 1 substantially equal to the pixel pitch P of each individual display device 1. The multi-display can thus have higher image quality.

In a multi-display including known display devices, for example, the pixel pitch between a display device and another display device, or specifically, the pixel pitch between the pixels (pixels P1) nearest the edge of the display device and the pixels (pixels P2) nearest the edge of the other display device and adjacent to the pixels P1, may differ from the pixel pitch on the display portion of each individual display device. Such a multi-display may have lower image quality. For example, a single mother substrate may be cut into multiple substrate segments, each of which is used to fabricate a display device. In this case, each display device includes a cutting margin that may cause the pixel pitch between the pixels P1 and the pixels P2 to differ from the pixel pitch on the display portion of each individual display device. This causes the multi-display to have a larger pixel pitch at the boundaries (bezels) between the display devices than in the display portions. The multi-display may thus periodically include portions with a larger pixel pitch, causing discomfort to a viewer viewing the image. In one or more embodiments of the present disclosure, the display device 1 can reduce this issue. The display device thus displays high definition images with a small pixel pitch on the display portions. A multi-display including such display devices has a small pixel pitch at the boundaries between the display devices to be equivalent to the pixel pitch of the display portions. The multi-display can thus display high definition images.

The display device 1 may have the second distance L2 shorter than the third distance L3. In this case, at least one of the first connection pads 5 on the first surface 2a is located at the second distance L2 from the edge substantially equal to the first distance L1 for the outermost pixel units 3 of the pixel units 3 arranged in a matrix. In some embodiments, at least one of the first connection pads 5 may be located between the outermost pixel units 3 and the edge 2d. This reduces variations in the pixel pitch P caused by the first connection pads 5 located within the pixel units 3 arranged in a matrix. This improves the image quality of the display device 1 and the image quality of a multi-display including multiple display devices 1.

The substrate 2 may be formed by cutting and dividing the mother substrate into multiple segments. The mother substrate may be cut with a laser beam irradiating its back surface (the surface corresponding to the second surface 2b). For the first distance L1 and the second distance L2 to be each shorter than the third distance L3, the mother substrate can include, on its back surface, a conductor-free area without the second connection pad 6 or other conductors at and around the cutting lines susceptible to heat from the laser beam for forming the substrate 2. The area at and around the cutting lines is more susceptible to heat from the laser beam on the back surface of the mother substrate than on the front surface (the surface corresponding to the first surface 2a). The conductor-free area at and around the cutting lines may thus be larger on the back surface of the mother substrate than on the front surface. This structure allows the second connection pad 6 to be less susceptible to heat from the laser beam, and also allows the first connection pad 5 to be less susceptible to heat from the laser beam.

The first connection pads 5 may all be located at the same distance (specifically, the second distance L2) from the edge 2d. In this case, the first connection pads 5 are all located between the pixel units 3 arranged in a matrix and the edge 2d on the first surface 2a. This reduces variations in the pixel pitch P caused by the first connection pads 5 located within the pixel units 3 arranged in a matrix. This effectively improves the image quality of the display device 1 and the image quality of a multi-display including multiple display devices 1.

The display device 1 has the third distance L3 longer than each of the first distance L1 and the second distance L2. The second connection pads 6 can thus be spaced from the edge 2d on the second surface 2b by a relatively long distance. For manufacturing the display device 1 with this structure, the mother substrate can be cut into substrate segments with a laser beam irradiating the second surface 2b with less thermal damage to the second connection pads 6, the electrode pads 31, and the first connection pads 5. Each substrate segment cut from the mother substrate includes a display device area to be the display device 1 including the second connection pads 6, the electrode pads 31, and the first connection pads 5. This effectively improves the image quality of the display device 1 and the image quality of a multi-display including multiple display devices 1.

The first distance L1 may be, for example, about 20 to 60 μm, about 30 to 50 μm, or about 40 μm. The second distance L2 may be, for example, about 20 to 60 μm, about 30 to 50 μm, or about 40 μm. The third distance L3 may be, for example, about 80 to 120 μm, about 90 to 110 μm, or about 100 μm.

The first electrode pads and the second electrode pads included in the outermost pixel units 3 on the first surface 2a may each be spaced from the edge 2d by a distance substantially equal to the first distance L1 as viewed in plan. This allows the first electrode pads and the second electrode pads connected to the TFT in each pixel unit 3 to be located at substantially the same distance from the edge 2d as the distance of the electrode pads 31 from the edge 2d. A display device 1 can thus be combined with another display device 1 to form a multi-display to effectively have a pixel pitch between these display devices 1 substantially equal to the pixel pitch P of each individual display device 1.

The third electrode pads and the fourth electrode pads on the second surface 2b may each be spaced from the edge 2d by a distance substantially longer than or equal to the third distance L3 as viewed in plan. For manufacturing the display device 1 with this structure, the mother substrate can be cut into substrate segments with a laser beam irradiating the second surface 2b with less thermal damage to the third electrode pads and the fourth electrode pads. Each substrate segment cut from the mother substrate includes a display device area to be the display device 1.

Each of the first distance L1 and the second distance L2 may be shorter than or equal to half the pixel pitch P. A display device 1 can thus be combined with another display device 1 to form a multi-display to have a pixel pitch between these display devices 1 equal to the pixel pitch P of each individual display device 1. This effectively improves the image quality of a multi-display including multiple display devices 1.

The first distance L1 and the second distance L2 may be equal to each other. In this case, the electrode pads 31 and the first connection pads 5 can be formed by, for example, photolithography or etching with easy preparation of a mask pattern and easy positioning of the mask pattern on the substrate 2. This allows the electrode pads 31 and the first connection pads 5 to be accurately formed, thus effectively improving the image quality of the display device 1.

Each of the first distance L1 and the second distance L2 may be shorter than half the third distance L3. In other words, the third distance L3 may be longer than or equal to twice the first distance L1 and longer than or equal to twice the second distance L2. In this case, the second connection pads 6 can be spaced from the edge 2d on the second surface 2b by a relatively long distance. For manufacturing the display device 1 with this structure, the mother substrate can be cut into substrate segments with a laser beam irradiating the second surface 2b with effectively reduced thermal damage to the second connection pads 6, the electrode pads 31, and the first connection pads 5. Each substrate segment cut from the mother substrate includes a display device area to be the display device 1 including the second connection pads 6, the electrode pads 31, and the first connection pads 5. This effectively improves the image quality of the display device 1.

In the display device 1, the second surface 2b may include a conductor-free area from the edge 2d to a certain distance. The certain distance is shorter than the third distance L3 from the edge 2d. The conductor-free area is an area with no conductor such as a conductive film and in which the second surface 2b of the substrate 2 is exposed. For manufacturing the display device 1 with this structure, the mother substrate can be cut into substrate segments with a laser beam irradiating the second surface 2b with less likelihood of short-circuiting between the second connection pads 6 caused by scattered conductive material for conductors. Each substrate segment cut from the mother substrate includes a display device area to be the display device 1 including the second connection pads 6, the electrode pads 31, and the first connection pads 5.

The above conductor-free area may include a thermal shield layer for reducing transfer of heat from the laser beam to the second connection pads 6. The thermal shield layer is, for example, an inorganic insulating layer of a material with a low thermal conductivity or a high melting point, such as silicon nitride, aluminum oxide, silicon carbide, tin oxide, zirconium oxide, titanium oxide, or calcium silicide.

A display device according to another embodiment of the present disclosure will now be described with reference to FIGS. 8A and 8B. FIG. 8A is a plan view of a display device according to another embodiment of the present disclosure, illustrating its main part in an enlarged manner. FIG. 8B is a cross-sectional view taken along line A7-A8 in FIG. 8A.

The cross-sectional view of FIG. 8B corresponds to the cross-sectional view of FIG. 6. Unlike the display device according to the above embodiment, in the present embodiment, the display device includes a third connection pad, multiple fourth connection pads, and multiple second side conductors. The other components are the same or similar to those in the above embodiment, and will not be described in detail. In FIG. 8A, the second side conductors are not illustrated.

The display device 1 may further include a third connection pad 11, multiple fourth connection pads 12, and multiple second side conductors 13.

The third connection pad 11 is on the first surface 2a adjacent to the edge 2d. The third connection pad 11 is connected to the pixel units 3. The third connection pad 11 is connected to the pixel units 3 with the first wiring pattern 8 or the second wiring pattern 9.

The third connection pad 11 is made of a conductive material. The third connection pad 11 may include a single metal layer, or multiple metal layers stacked on one another. In the present embodiment, the third connection pad 11 includes multiple metal layers stacked on one another, and has a structure the same or similar to the structure of the first connection pad 5 illustrated in FIGS. 5 and 6. The same or similar components are denoted by like reference numerals as those for the first connection pad 5 and will not be described in detail.

The fourth connection pads 12 are on the second surface 2b adjacent to the edge 2d. The fourth connection pads 12 are connected to the VDD terminal 41 or VSS terminal 42 in the power supply circuit 4 with the third wiring pattern 10 located on the second surface 2b. For the third connection pad 11 being connected to the first wiring pattern 8, the fourth connection pads 12 are connected to the VDD terminal 41. For the third connection pad 11 being connected to the second wiring pattern 9, the fourth connection pads 12 are connected to the VSS terminal 42.

The fourth connection pads 12 are made of a conductive material. The fourth connection pads 12 may each include a single metal layer, or multiple metal layers stacked on one another. In the present embodiment, the fourth connection pads 12 each include a single metal layer, and have a structure the same or similar to the structure of the second connection pad 6 illustrated in FIGS. 5 and 6. The same or similar components are denoted by like reference numerals as those for the second connection pad 6 and will not be described in detail.

As illustrated in, for example, FIG. 8B, the second side conductors 13 extend from the side surface 2c to the first surface 2a and to the second surface 2b. The second side conductors 13 connect the third connection pad 11 and the fourth connection pads 12.

The second side conductors 13 in the present embodiment have a structure and a method of formation the same or similar to those for the side conductors 7. The structure and the method of formation are thus not described in detail.

In the present embodiment, the display device 1 includes multiple wiring patterns on the second surface 2b connected to the fourth connection pads 12 to substantially increase the area and/or the cross section of the wiring for feeding the power supply voltage. This structure reduces the electric resistance of the circuit for feeding power supply voltage to the pixel units 3 and reduces drops of the power supply voltage to be supplied to the pixel units 3. The display device 1 thus has higher image quality and higher reliability.

As illustrated in, for example, FIG. 8A, in the display device 1, the third connection pad 11 may have a center C11 shifted from a center C12 of each fourth connection pad 12 as viewed in plan. This increases the positioning flexibility of the third connection pad 11 and the fourth connection pads 12. This allows the third connection pad 11 and the fourth connection pads 12 to be located adjacent to the edge 2d, achieving higher definition and a narrower bezel of the display device 1. The center C11 and the center C12 may be shifted in the direction along the edge 2d (the vertical direction in FIG. 8A), in a direction intersecting with the edge 2d, for example, orthogonal to the edge 2d (the horizontal direction in FIG. 8A), or in the directions along and orthogonal to the edge 2d.

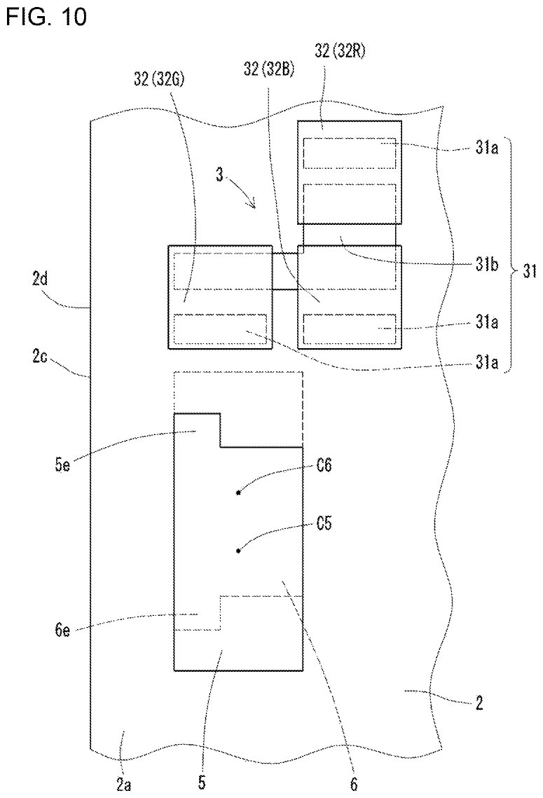

Unlike in the display device 1 in FIG. 3, the first connection pad 5 may include an extending portion 5e at the end in the shift direction (the direction in which the second connection pad 6 is shifted from the first connection pad 5 as viewed in plan) adjacent to the edge 2d, as illustrated in FIG. 10. To form the side conductor 7 by applying and firing a conductive paste, the structure allows the conductive paste to be guided easily in the depth direction of the first connection pad 5 with less overflow outside the first connection pad 5. The above shift direction is along the edge 2d but may be any other direction. In other words, the first connection pad 5 may include the extending portion 5e at the end in the shift direction adjacent to the edge 2d. The extending portion 5e may have a size (area) of, but not limited to, about 5 to 30% of the size (area) of the body of the first connection pad 5. The first connection pad 5 may include the extending portion 5e at each end adjacent to the edge 2d. This structure increases the above effects. Similarly, the second connection pad 6 may include an extending portion 6e at the end in the shifted direction (the direction in which the first connection pad 5 is shifted from the second connection pad 6 as viewed in plan) adjacent to the edge 2d. To form the side conductor 7 by applying and firing a conductive paste, the structure allows the conductive paste to be guided easily in the depth direction of the second connection pad 6 with less overflow outside the second connection pad 6. The above shift direction is along the edge 2d but may be any other direction. In other words, the second connection pad 6 may include the extending portion 6e at the end in the shift direction adjacent to the edge 2d. The extending portion 6e may have a size (area) of, but not limited to, about 5 to 30% of the size (area) of the body of the second connection pad 6. The first connection pad 5 may include the extending portion 6e at each end adjacent to the edge 2d. This structure increases the above effects.

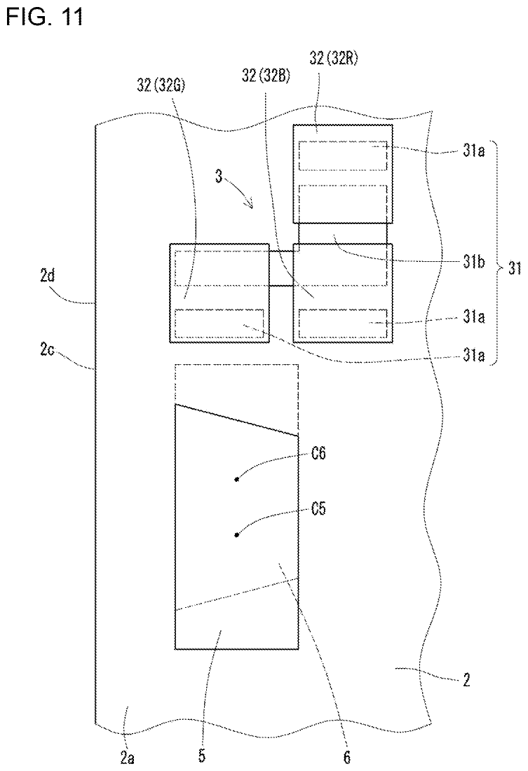

Unlike in the display device 1 in FIG. 3, the first connection pad 5 may be in the shape of a trapezoid with its lower base (the side adjacent to the edge 2d) extended in the shift direction (the direction in which the second connection pad 6 is shifted from the first connection pad 5 as viewed in plan), as illustrated in FIG. 11. This structure has the same or similar effects as the structure illustrated in FIG. 10. The trapezoidal first connection pad 5 has its upper base opposite to the edge 2d. The second connection pad 6 may also be in the shape of a trapezoid with its lower base (the side adjacent to the edge 2d) extended in the shift direction (the direction in which the first connection pad 5 is shifted from the second connection pad 6 as viewed in plan). This structure has the same or similar effects as the structure illustrated in FIG. 10. The trapezoidal second connection pad 6 has its upper base opposite to the edge 2d.

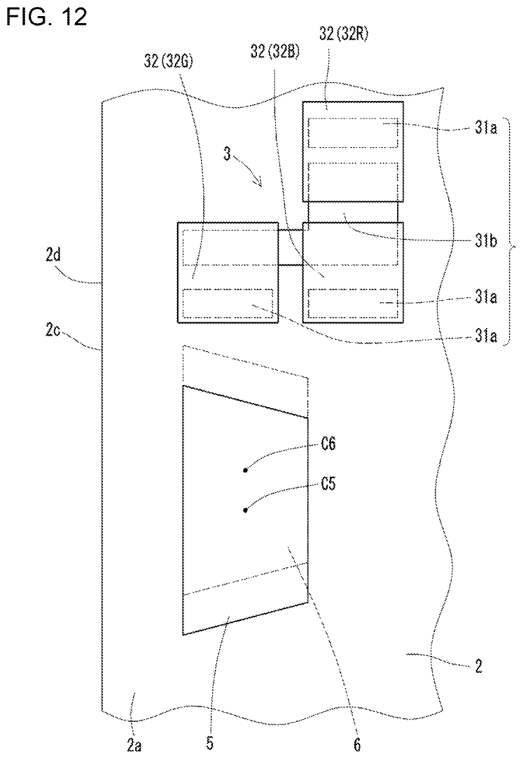

Unlike in the display device 1 in FIG. 3, the first connection pad 5 may be in the shape of a trapezoid with its lower base (the side adjacent to the edge 2d) extended in the shift direction (the direction in which the second connection pad 6 is shifted from the first connection pad 5 as viewed in plan) and in the direction opposite to the shift direction, as illustrated in FIG. 12. This structure has the same or similar, or further effects as the structure illustrated in FIG. 10. More specifically, to form the side conductor 7 by applying and firing a conductive paste, the structure allows the conductive paste to be guided more easily in the depth direction of the first connection pad 5 with further less overflow outside the first connection pad 5. The trapezoidal first connection pad 5 has its upper base opposite to the edge 2d. The second connection pad 6 may also be in the shape of a trapezoid with its lower base (the side adjacent to the edge 2d) extended in the shift direction (the direction in which the first connection pad 5 is shifted from the second connection pad 6 as viewed in plan) and in the direction opposite to the shift direction. This structure has the same or similar, or further effects as the structure illustrated in FIG. 10. More specifically, to form the side conductor 7 by applying and firing a conductive paste, the structure allows the conductive paste to be guided more easily in the depth direction of the second connection pad 6 with further less overflow outside the second connection pad 6. The trapezoidal second connection pad 6 has its upper base opposite to the edge 2d.

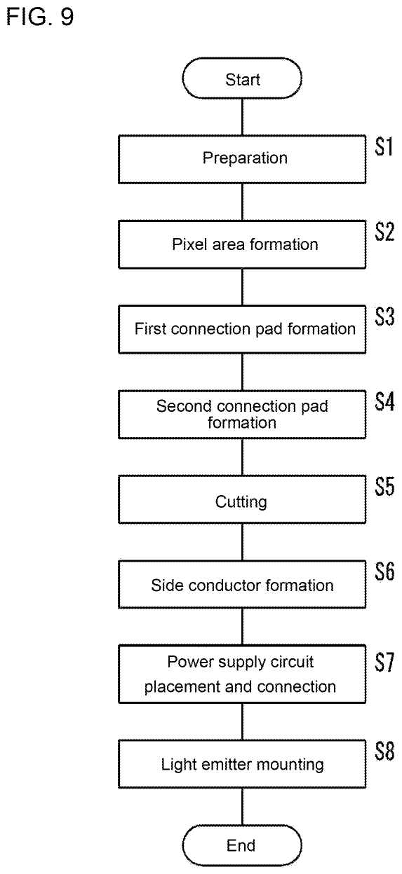

A method for manufacturing the display device according to an embodiment of the present disclosure will now be described. FIG. 9 is a flowchart of a method for manufacturing the display device according to an embodiment.

In the present embodiment, the method for manufacturing the display device includes preparation S1, pixel area formation S2, first connection pad formation S3, second connection pad formation S4, and cutting S5.

The preparation S1 is the process of preparing a mother substrate for manufacturing the display device 1. The mother substrate has a first surface and a second surface opposite to the first surface. The mother substrate includes at least one display device area to be the display device 1.

The pixel area formation S2 is the process of forming multiple pixel areas arranged in a matrix at a predetermined pitch in the display device area on the first surface 2a. Each pixel area herein refers to, for example, the pixel unit 3 illustrated in FIG. 4 excluding the light emitter 32. The pixel areas can be formed with a known method, such as a thin film formation method (e.g., plating, vapor deposition, or CVD), photolithography, or etching.

The first connection pad formation S3 is the process of forming the first connection pads 5 in the display device area on the first surface 2a adjacent to the edge of the display device area to connect the first connection pads 5 to the electrode pads 31. The first connection pads 5 can be formed with a known method, such as a thin film formation method (e.g., plating, vapor deposition, or CVD), photolithography, or etching.

The second connection pad formation S4 is the process of forming the second connection pads 6 in the display device area on the second surface 2b adjacent to the edge of the display device area to connect the second connection pads 6 to the first connection pads 5. In the second connection pad formation S4, the second connection pads 6 are formed to cause at least one of the first connection pads 5 to have the center C5 shifted from the center C6 of the second connection pad 6 connected to the first connection pad 5 in the direction along the edge of the display device area as viewed in plan. The second connection pads 6 can be formed with a known method, such as a thin film formation method (e.g., plating, vapor deposition, or CVD), photolithography, or etching.

In the second connection pad formation S4, the second connection pads 6 may be formed to cause at least one of the first connection pads 5 to have the center C5 shifted from the center C6 of the second connection pad 6 connected to the first connection pad 5 in the directions along and orthogonal to the edge of the display device areas.

In the second connection pad formation S4, the second connection pads 6 may be formed to cause the smallest value of the distances between the edge of the display device area and the electrode pads 31 and the smallest value of the distances between the edge of the display device area and the first connection pads 5 to be each shorter than the smallest value of the distances between the edge of the display device area and the second connection pads 6 as viewed in plan.

The pixel area formation S2, the first connection pad formation S3, and the second connection pad formation S4 may be performed in any order. The pixel area formation S2 and the first connection pad formation S3 may be performed at the same time.

The cutting S5 is the process of cutting the mother substrate along the edge of the display device area into substrate segments (display device substrates) each including the display device area. The cutting S5 can be performed by, for example, mechanical scribing or laser scribing.

The cutting S5 may be performed by laser scribing using a laser beam emitted from, for example, a CO₂ laser or a YAG laser to irradiate the second surface 2b of the mother substrate along the edge of the display device area to separate the display device area from the mother substrate. The mother substrate may be cut by laser scribing more accurately than by mechanical scribing. The second connection pads 6 are spaced from the edge of the display device area by a relatively long distance, and are thus less susceptible to damage from the laser beam. The manufactured display device 1 thus has high image quality.

In the present embodiment, the method for manufacturing the display device includes, after the cutting S5, side conductor formation S6, power supply circuit placement and connection S7, and light emitter mounting S8.

The side conductor formation S6 is the process of forming the side conductors 7 extending from the side surface 2c to the first surface 2a and to the second surface 2b of the display device substrate resulting from the cutting S5. The side surface 2c connects the first surface 2a and the second surface 2b. The side conductors 7 connect the first wiring pads 51 and the second wiring pads 52.

The side conductors 7 may include a conductive paste containing conductive particles of, for example, Ag, Cu, Al, or stainless steel, an uncured resin component, an alcohol solvent, and water. The conductive paste may be applied to intended portions from the side surface 2c to the first surface 2a and to the second surface 2b of the display device substrate and cured by heating, photocuring using ultraviolet ray irradiation, or a combination of photocuring and heating. The side conductors 7 may also be formed with a thin film formation method such as plating, vapor deposition, or CVD. The display device substrate may have the side surface 2c with preformed grooves in the portions to receive the side conductors 7. This allows the conductive paste that forms the side conductors 7 to be easily received in the intended portions on the side surface 2c of the display device substrate.

The power supply circuit placement and connection S7 is the process of placing the power supply circuit 4 on the second surface 2b and connecting the power supply circuit 4 to the second connection pads 6. In the power supply circuit placement and connection S7, the power supply circuit 4 may be prepared in advance and mounted on the second surface 2b of the display device substrate, or may be directly formed on the second surface 2b of the display device substrate with a known method, such as a thin film formation method (e.g., plating, vapor deposition, or CVD), photolithography, or etching.

The light emitter mounting S8 is the process of mounting the light emitters 32 on the pixel areas. The light emitters 32 may be, for example, LEDs or micro-LEDs. In the light emitter mounting S8, three light emitters 32R, 32G, and 32B may be mounted on the respective pixel areas.

The side conductor formation S6, the power supply circuit placement and connection S7, and the light emitter mounting S8 may be performed in any order.

The display device 1 manufactured with the above method can form a multi-display with higher image quality.

### INDUSTRIAL APPLICABILITY

Although embodiments of the present disclosure have been described in detail, the present disclosure is not limited to the embodiments described above, and may be changed or modified in various manners without departing from the spirit and scope of the present disclosure. The components described in the above embodiments may be entirely or partially combined as appropriate unless any contradiction arises. In one or more embodiments of the present disclosure, the display device can be used in various electronic devices. Such electronic devices include, for example, automobile route guidance systems (car navigation systems), ship route guidance systems, aircraft route guidance systems, smartphones, mobile phones, tablets, personal digital assistants (PDAs), video cameras, digital still cameras, electronic organizers, electronic dictionaries, personal computers, copiers, terminals for game devices, television sets, product display tags, price display tags, programmable display devices for industrial use, car audio systems, digital audio players, facsimile machines, printers, automatic teller machines (ATMs), vending machines, digital display watches, smartwatches, and information displays at stations, airports, and other facilities.

### REFERENCE SIGNS

1 display device
2 substrate
2a first surface
2b second surface
2c side surface
2d edge
3 pixel unit
31 electrode pad
31a anode pad
31b cathode pad
32, 32R, 32G, 32B light emitter
32a anode terminal
32b cathode terminal
33, 34, 35, 36 insulating layer
37 transparent conductive layer
4 power supply circuit
41 VDD terminal
42 VSS terminal
5 first connection pad
5e extending portion
51 first wiring pad
52 second wiring pad
53, 54 metal layer
55, 56, 57 insulating layer
58 transparent conductive layer
6 second connection pad
6e extending portion
61 third wiring pad
62 fourth wiring pad
63 metal layer
64 insulating protective layer
65 transparent conductive layer
7 side conductor (connection conductor, side wiring)
8 first wiring pattern
9 second wiring pattern
10 third wiring pattern
11 third connection pad
12 fourth connection pad
13 second side conductor

1. A display device comprising:
a substrate having a first surface and a second surface opposite to the first surface;
a pixel unit on the first surface, the pixel unit including a light emitter;
a first connection pad on the first surface adjacent to an edge of the substrate, the first connection pad being connected to the pixel unit;
a second connection pad on the second surface adjacent to the edge; and
a connection conductor extending from the first surface to the second surface, the connection conductor connecting the first connection pad and the second connection pad,
wherein the first connection pad has a center at a position different from a center of the second connection pad as viewed in plan.

2. The display device according to claim 1, wherein
the first connection pad and the second connection pad include an overlap portion as viewed in plan.

3. The display device according to claim 1, wherein
the first connection pad has the center shifted from the center of the second connection pad in a direction along the edge of the substrate.

4. The display device according to claim 1, wherein
the center of the first connection pad is shifted from the center of the second connection pad in a direction intersecting with the edge of the substrate.

5. The display device according to claim 1, wherein
the substrate has a side surface connecting the first surface and the second surface, and
the connection conductor includes a side conductor extending from the first surface through the side surface to the second surface.

6. The display device according to claim 5, wherein
the side conductor connects the first connection pad and a plurality of the second connection pads.

7. The display device according to claim 6, wherein
the side conductor is thicker on the first connection pad than on the plurality of the second connection pads.

8. A display device comprising:
a substrate having a first surface and a second surface opposite to the first surface;
a plurality of pixel units on the first surface, each of the plurality of pixel units including a light emitter and an electrode pad connected to the light emitter;
a power supply circuit on the second surface to generate a power supply voltage to be supplied to the plurality of light emitters;
a plurality of first connection pads on the first surface adjacent to an edge of the substrate, the plurality of first connection pads being connected to the plurality of pixel units;
a plurality of second connection pads on the second surface adjacent to the edge, the plurality of second connection pads being connected to the power supply circuit; and
a plurality of connection conductors extending from the first surface to the second surface, the plurality of connection conductors connecting the plurality of first connection pads and the plurality of second connection pads,
wherein a first distance and a second distance are each shorter than a third distance as viewed in plan, the first distance is a smallest value of distances between the edge and the plurality of electrode pads, the second distance is a smallest value of distances between the edge and the plurality of first connection pads, and the third distance is a smallest value of distances between the edge and the plurality of second connection pads.

9. The display device according to claim 8, wherein
the substrate has a side surface connecting the first surface and the second surface, and
the plurality of connection conductors include a plurality of side conductors extending from the side surface to the first surface and to the second surface.

10. The display device according to claim 8, wherein
each of the first distance and the second distance is shorter than or equal to half a pixel pitch of the plurality of pixel units.

11. The display device according to claim 8, wherein
the first distance and the second distance are equal to each other.

12. The display device according to claim 8, wherein
each of the first distance and the second distance is shorter than half the third distance.

13. The display device according to claim 8, wherein
the second surface includes a conductor-free area from the edge to a certain distance, and
the certain distance is shorter than the third distance.

14. The display device according to claim 1, wherein
the light emitter includes a micro-light-emitting diode.

15. A method for manufacturing a display device, the method comprising:
preparing a mother substrate having a first surface and a second surface opposite to the first surface, the mother substrate including at least one display device area;
forming a plurality of pixel areas in the at least one display device area on the first surface, each of the plurality of pixel areas including an electrode pad;
forming a plurality of first connection pads in the at least one display device area on the first surface adjacent to an edge of the at least one display device area to connect the plurality of first connection pads to the plurality of electrode pads;
forming a plurality of second connection pads in the at least one display device area on the second surface adjacent to the edge of the at least one display device area to cause a smallest value of distances between the edge of the at least one display device area and the plurality of electrode pads and a smallest value of distances between the edge and the plurality of first connection pads to be each shorter than a smallest value of distances between the edge and the plurality of second connection pads as viewed in plan; and
cutting the mother substrate along the edge of the at least one display device area into a display device substrate including the at least one display device area.

16. The method according to claim 15, wherein
the cutting includes irradiating the second surface with a laser beam along the edge to cut the mother substrate.

17. The method according to claim 15, further comprising:
forming a plurality of side conductors extending from a side surface connecting the first surface and the second surface of the display device substrate to the first surface and to the second surface, the plurality of side conductors connecting the plurality of first connection pads and the plurality of second connection pads;
placing a power supply circuit on the second surface and connecting the power supply circuit to the plurality of second connection pads; and
mounting a light emitter on each of the plurality of pixel areas,
the forming the plurality of side conductors, the placing and connecting the power supply circuit, and the mounting the light emitter being performed after the cutting.
